(19) United States
(12) Patent Application Publication
(10) Pub. No.: US 2024/0008326 A1
(43) Pub. Date: Jan. 4, 2024

(54) DISPLAY PANEL, DRIVING METHOD AND DISPLAY APPARATUS

(71) Applicants: Chengdu BOE Optoelectronics Technology Co., Ltd., Sichuan Province (CN); BOE Technology Group Co., Ltd., Beijing (CN)

(72) Inventor: Zhu WANG, Beijing (CN)

(21) Appl. No.: 18/250,276

(22) PCT Filed: Nov. 18, 2020
(86) PCT No.: PCT/CN2020/129900

§ 371 Date: Apr. 24, 2023

(51) Int. Cl. H10K 59/131; H10K 59/121

(52) U.S. Cl. CPC H10K 59/131; H10K 59/1213; H10K 59/1216

(57) ABSTRACT

A display panel, a driving method and a display apparatus are disclosed. The display panel includes: a substrate, an active semiconductor layer, a gate insulating layer, a first conductive layer, an interlayer dielectric layer, a second conductive layer, a first interlayer insulating layer, a third conductive layer including a plurality of first signal lines, a second interlayer insulating layer, a fourth conductive layer including a plurality of second signal lines stacked in that order. Orthographic projections of the first signal lines on the substrate and orthographic projections of the second signal lines on the substrate are arranged in an intersecting manner.

### CROSS REFERENCE TO RELATED APPLICATIONS

This application is a national phase entry under 35 U.S.C. § 371 of International Application No. PCT/CN2020/129900, filed on Nov. 18, 2020, the entire content of which is incorporated herein by reference.

### FIELD

Embodiments of the disclosure relate to the field of display technology, and particularly relate to a display panel, a driving method and a display apparatus.

### BACKGROUND

With the continuous development of display technology, organic light-emitting diode (OLED) display panels, which feature self-luminescence, wide viewing angle, high contrast, low power consumption, and high response speed, have been increasingly applied to electronic apparatuses.

### SUMMARY

A display panel provided in an embodiment of the disclosure includes: a substrate including a plurality of sub-pixels; an active semiconductor layer on the substrate; a gate insulating layer on a side of the active semiconductor layer facing away from the substrate; a first conductive layer on a side of the gate insulating layer facing away from the substrate; an interlayer dielectric layer on a side of the first conductive layer facing away from the substrate; a second conductive layer on a side of the interlayer dielectric layer facing away from the substrate; a first interlayer insulating layer on a side of the second conductive layer facing away from the substrate; a third conductive layer on a side of the first interlayer insulating layer facing away from the substrate, where the third conductive layer includes a plurality of first signal lines that are spaced from each other; a second interlayer insulating layer on a side of the third conductive layer facing away from the substrate; and a fourth conductive layer on a side of the second interlayer insulating layer facing away from the substrate, where the fourth conductive layer includes a plurality of second signal lines that are spaced from each other. Here, orthographic projections of the first signal lines on the substrate intersect with orthographic projections of the second signal lines on the substrate.

In some embodiments, the first signal lines are data lines, and the second signal lines are power lines.

In some embodiments, the first conductive layer includes a plurality of scanning lines that are spaced from each other, and the scanning lines have the same extension direction as the power lines; the fourth conductive layer further includes a plurality of reset lines that are spaced from each other, and the reset lines have the same extension direction as the power lines. For a power line, a scanning line and a reset line corresponding to one row of sub-pixel circuits, an orthographic projection of the scanning line on the substrate is located between an orthographic projection of the power line on the substrate and an orthographic projection of the reset line on the substrate.

In some embodiments, a pixel circuit includes a driving transistor, a data writing transistor, a reset transistor, and a storage capacitor; a first electrode of the driving transistor is electrically connected with the power line, and a second electrode of the driving transistor is electrically connected with a light emitting element; a first conductive plate of the storage capacitor is electrically connected with a gate of the driving transistor, and a second conductive plate of the storage capacitor is electrically connected with the second electrode of the driving transistor; a gate of the data writing transistor is electrically connected with the scanning line, a first electrode of the data writing transistor is electrically connected with the data line, and a second electrode of the data writing transistor is electrically connected with the gate of the driving transistor; and a gate of the reset transistor is electrically connected with the scanning line, a first electrode of the reset transistor is electrically connected with the reset line, and a second electrode of the reset transistor is electrically connected with the second electrode of the driving transistor.

In some embodiments, the active semiconductor layer includes an active zone of the driving transistor, the first conductive layer includes the first conductive plate of the storage capacitor, and the first conductive plate of the storage capacitor is reused as the gate of the driving transistor; in the sub-pixel, an orthographic projection of the first conductive plate of the storage capacitor on the substrate has an overlapping region with an orthographic projection of a channel zone of the active zone of the driving transistor on the substrate; and in the sub-pixel, the channel zone of the active zone of the driving transistor includes a first driving channel zone and a second driving channel zone connected with each other, where the first driving channel zone extends in a first direction, the second driving channel zone extends in a third direction, and an included angle β between the first direction and the third direction satisfies 0°<β≤90°.

In some embodiments, the active semiconductor layer further includes an active zone of the reset transistor, where the active zone of the reset transistor extends in the first direction, and the active zone of the reset transistor is located at a side of the second driving channel zone of the driving transistor facing away from the first driving channel zone; and in the same sub-pixel, a conducting drain zone of the active zone of the reset transistor is connected with the second driving channel zone of the driving transistor.

In some embodiments, the active semiconductor layer further includes an active zone of the data writing transistor, and the active zone of the data writing transistor is spaced from the active zone of the reset transistor and the active zone of the driving transistor separately, where the active zone of the data writing transistor extends in the first direction; and in the same sub-pixel, an orthographic projection of the active zone of the data writing transistor in a second direction is located at a side of an orthographic projection of the second driving channel zone of the driving transistor in the second direction facing away from an orthographic projection of the active zone of the reset transistor in the second direction.

In some embodiments, in the same sub-pixel, a channel zone of the active zone of the data writing transistor and a channel zone of the active zone of the reset transistor are arranged in the second direction.

In some embodiments, one row of the sub-pixels correspond to one scanning line; and in the same sub-pixel, the orthographic projection of the scanning line on the substrate has an overlapping region with each of the channel zone of the active zone of the data writing transistor and the channel zone of the active zone of the reset transistor.

In some embodiments, the second conductive layer includes a data adaptor part located in each sub-pixel; the first conductive plate of the storage capacitor includes a first conductive plate body part and a first conductive plate protrusion part electrically connected with each other; and in the same sub-pixel, a first end of the data adaptor part is electrically connected with a conducting drain zone of the active zone of the data writing transistor through a first via hole, and a second end of the data adaptor part is electrically connected with the first conductive plate protrusion part through a second via hole, where the first via hole runs through the gate insulating layer and the interlayer dielectric layer, and the second via hole runs through the interlayer dielectric layer.

In some embodiments, the second conductive layer further includes the second conductive plate of the storage capacitor, where the second conductive plate of the storage capacitor includes a second conductive plate body part and a second conductive plate protrusion part electrically connected with each other; and in the same sub-pixel, the second conductive plate protrusion part is electrically connected with the conducting drain zone of the active zone of the reset transistor through a third via hole, where the third via hole runs through the interlayer dielectric layer and the gate insulating layer.

In some embodiments, in the same sub-pixel, an orthographic projection of the first conductive plate body part on the substrate has an overlapping region with an orthographic projection of the second conductive plate body part on the substrate.

In some embodiments, the second conductive plate of the storage capacitor further includes: a second conductive plate compensation part electrically connected with the second conductive plate body part and the second conductive plate protrusion part separately, where the second conductive plate compensation part is located at a corner formed by the second conductive plate body part and the second conductive plate protrusion part; and in the same sub-pixel, an orthographic projection of the second conductive plate compensation part on the substrate has an overlapping region with the orthographic projection of the first conductive plate body part on the substrate.

In some embodiments, in the same sub-pixel, the orthographic projection of the first conductive plate body part on the substrate has an overlapping region with an edge of an orthographic projection of the second conductive plate protrusion part on the substrate close to the orthographic projection of the second conductive plate body part on the substrate.

In some embodiments, one column of the sub-pixels correspond to one data line; and in the same sub-pixel, the data line is electrically connected with a conducting source zone of the active zone of the data writing transistor through a fourth via hole, where the fourth via hole runs through the first interlayer insulating layer, the interlayer dielectric layer and the gate insulating layer, and an orthographic projection of the fourth via hole on the substrate is located at a side of the orthographic projection of the scanning line on the substrate facing away from the orthographic projection of the first conductive plate of the storage capacitor on the substrate.

In some embodiments, one power line corresponds to at least one row of the sub-pixels; and the third conductive layer further includes a plurality of power adaptor parts that are spaced from each other, where in the same sub-pixel, the power line is electrically connected with the power adaptor part through a fifth via hole, and the power adaptor part is electrically connected with a conducting source zone of the active zone of the driving transistor through a sixth via hole, where the fifth via hole runs through the second interlayer insulating layer, and the sixth via hole runs through the first interlayer insulating layer, the interlayer dielectric layer, and the gate insulating layer.

In some embodiments, one reset line corresponds to at least one row of the sub-pixels; and the third conductive layer further includes a plurality of reset adaptor parts that are spaced from each other; and in the same sub-pixel, the reset line is electrically connected with the reset adaptor part through a seventh via hole, and the reset adaptor part is electrically connected with a conducting source zone of the active zone of the reset transistor through an eighth via hole, where the seventh via hole runs through the second interlayer insulating layer, and the eighth via hole runs through the first interlayer insulating layer, the interlayer dielectric layer, and the gate insulating layer.

In some embodiments, the fourth conductive layer further includes a plurality of anode connecting parts that are spaced from each other; and the third conductive layer further includes a plurality of anode adaptor parts that are spaced from each other, where one sub-pixels includes one anode connecting part and one anode adaptor part; and in the same sub-pixel, the anode connecting part is electrically connected with a first end of the anode adaptor part through a ninth via hole, and a second end of the anode adaptor part is electrically connected with the second conductive plate of the storage capacitor through a tenth via hole, where the ninth via hole runs through the second interlayer insulating layer, and the tenth via hole runs through the first interlayer insulating layer.

In some embodiments, in the same sub-pixel, an orthographic projection of the ninth via hole on the substrate and an orthographic projection of the tenth via hole on the substrate are arranged in the first direction.

In some embodiments, in the same sub-pixel, the orthographic projection of the tenth via hole on the substrate is located at a side of the orthographic projection of the ninth via hole on the substrate facing away from an orthographic projection of the third via hole on the substrate.

In some embodiments, in the same sub-pixel, the orthographic projection of the ninth via hole on the substrate has an overlapping region with the orthographic projection of the second conductive plate compensation part on the substrate.

In some embodiments, in at least one sub-pixel, an orthographic projection of the anode connecting part on the substrate has an overlapping region with an orthographic projection of the data line on the substrate.

In some embodiments, in the same sub-pixel, the orthographic projection of the anode connecting part on the substrate has an overlapping region with an orthographic projection of a corner between the first driving channel zone and the second driving channel zone on the substrate.

In some embodiments, in at least one sub-pixel, an overlapping region between the orthographic projection of the anode connecting part on the substrate and the orthographic projection of the second driving channel zone on the substrate is larger than an overlapping region between the orthographic projection of the anode connecting part on the substrate and the orthographic projection of the first driving channel zone on the substrate.

In some embodiments, in the same sub-pixel, an orthographic projection of a part of the anode adaptor part close to the ninth via hole on the substrate has an overlapping region with the orthographic projection of the corner between the first driving channel zone and the second driving channel zone on the substrate.

In some embodiments, in the same column of the sub-pixels, the anode connecting parts are arranged in the first direction and are not arranged on the same straight line; and in the same row of the sub-pixels, the anode connecting parts are arranged in the first direction and are not arranged on the same straight line.

In some embodiments, in the same column of the sub-pixels, the anode adaptor parts are arranged on the same straight line in the first direction; and in the same row of the sub-pixels, the anode adaptor parts are arranged on the same straight line in the second direction.

In some embodiments, in two adjacent sub-pixels, orthographic projections of pixel circuits on the substrate are arranged in a mirror symmetry manner.

In some embodiments, two adjacent rows of sub-pixels constitute one row group, and different row groups include different sub-pixels; and two scanning lines corresponding to the row group have a row symmetry axis in a row direction, and orthographic projections of pixel circuits in the sub-pixels of the same row group on the substrate are arranged in a mirror symmetry manner with respect to the row symmetry axis.

In some embodiments, two adjacent columns of sub-pixels in the same row group constitute one column group, and different column groups include different sub-pixels; and two data lines corresponding to the column group have a column symmetry axis in a column direction, and orthographic projections of pixel circuits in the same column group of sub-pixels on the substrate are arranged in a mirror symmetry manner with respect to the column symmetry axis.

In some embodiments, the display panel further includes: a first electrode layer on aside of the fourth conductive layer facing away from the substrate, where the first electrode layer includes an anode located in each sub-pixel; and a pixel defining layer on a side of the first electrode layer facing away from the substrate, where the pixel defining layer includes a plurality of opening regions, one anode corresponds to one opening region, and in the same sub-pixel, an orthographic projection of the opening region on the substrate is located within an orthographic projection of the corresponding anode on the substrate; and the orthographic projection of the power line on the substrate passes through orthographic projections of opening regions in at least two sub-pixels on the substrate.

In some embodiments, the same row group of sub-pixels share one power line; and orthographic projections of pixel circuits located in the same column and on two sides of the power line on the substrate are arranged symmetrically with respect to the orthographic projection of the power line on the substrate.

In some embodiments, the active semiconductor layer further includes a plurality of driving protrusion parts; and conducting source zones of driving transistors in two sub-pixels in the same column of the row group are electrically connected with one driving protrusion part, where in the same driving transistor, the conducting source zone is electrically connected with the first driving channel zone, and the conducting source zone and the first driving channel zone electrically connected with each other extend in the same direction; in the same column of the sub-pixels, an orthographic projection of the driving protrusion part on the substrate is on a side of an orthographic projection of the conducting source zone on the substrate facing away from the orthographic projection of the data line on the substrate; and the power adaptor part is electrically connected, through the sixth via hole, to the driving protrusion part electrically connected with the driving transistor, and an orthographic projection of the driving protrusion part electrically connected with the driving transistor on the substrate covers an orthographic projection of the sixth via hole on the substrate.

In some embodiments, in the same column of the sub-pixels, an extension line of the active zone of the reset transistor in the column direction has an overlapping region with the driving protrusion part.

In some embodiments, in the same column of the sub-pixels, the orthographic projection of the fifth via hole on the substrate is located at a side of the orthographic projection of the sixth via hole on the substrate facing away from the orthographic projection of the data line on the substrate.

In some embodiments, the same column group of driving transistors share one power adaptor part.

In some embodiments, the orthographic projection of the power line on the substrate covers an orthographic projection of the power adaptor part electrically connected with the power line on the substrate.

In some embodiments, two adjacent rows of sub-pixels located in different row groups share one reset line; and orthographic projections of pixel circuits located in the same column and on two sides of the reset line on the substrate are arranged symmetrically with respect to the orthographic projection of the reset line on the substrate.

In some embodiments, for two rows of sub-pixels sharing the same reset line, two adjacent columns of sub-pixels in the two rows of sub-pixels share one reset adaptor part.

In some embodiments, the orthographic projection of the reset line on the substrate covers an orthographic projection of the reset adaptor part electrically connected with the reset line on the substrate.

In some embodiments, in the same column of the sub-pixels, an orthographic projection of the seventh via hole on the substrate is on a side of an orthographic projection of the eighth via hole on the substrate facing away from the orthographic projection of the data line on the substrate.

In some embodiments, a data signal on the data line is transmitted to the conducting source zone of the active zone of the data writing transistor through the fourth via hole; the data signal transmitted to the conducting source zone of the active zone of the data writing transistor is transmitted to the conducting drain zone of the active zone of the data writing transistor through the channel zone of the active zone of the data writing transistor; the data signal transmitted to the conducting drain zone of the active zone of the data writing transistor is transmitted to the data adaptor part through the first via hole; and the data signal transmitted to the data adaptor part is transmitted to the first conductive plate of the storage capacitor through the second via hole.

In some embodiments, a reset signal on the reset line is transmitted to the conducting source zone of the active zone of the reset transistor through the eighth via hole; the reset signal transmitted to the conducting source zone of the active zone of the reset transistor is transmitted to the conducting drain zone of the active zone of the reset transistor through the channel zone of the active zone of the reset transistor; the reset signal transmitted to the conducting drain zone of the active zone of the reset transistor is transmitted to the second conductive plate of the storage capacitor through the third via hole; the reset signal transmitted to the second conductive plate of the storage capacitor is transmitted to the anode adaptor part through the tenth via hole; and the reset signal transmitted to the anode adaptor part is transmitted to the anode connecting part through the ninth via hole.

In some embodiments, a power signal on the power line is transmitted to the power adaptor part through the fifth via hole; and the power signal transmitted to the power adaptor part is transmitted, through the sixth via hole, to the driving protrusion part electrically connected with the driving transistor.

In some embodiments, a driving current generated by the driving transistor is transmitted to the second conductive plate of the storage capacitor through the third via hole; the driving current transmitted to the second conductive plate of the storage capacitor is transmitted to the anode adaptor part through the tenth via hole; and the driving current transmitted to the anode adaptor part is transmitted to the anode connecting part through the ninth via hole.

A display apparatus provided in an embodiment of the disclosure includes the display panel.

A driving method for the display panel provided in an embodiment of the disclosure includes: in a reset stage, providing a turn-on control signal to each scanning line simultaneously, providing a reset signal to each reset line simultaneously, and providing an initialization signal to each data line simultaneously, so as to initialize a gate of each driving transistor simultaneously and reset each light emitting element simultaneously; in a data writing stage, providing turn-on control signals to the scanning lines successively, providing the reset signals to the reset lines successively, and providing corresponding data signals to the data lines while the turn-on control signals are applied to the scanning lines, so as to input the data signal to the gate of each driving transistor; and in a light emitting stage, providing a turn-off control signal to each scanning line simultaneously, and generating a driving current by each driving transistor, so as to drive the light emitting element electrically connected with the driving transistor to emit light.

### BRIEF DESCRIPTION OF THE DRAWINGS

FIG. 1 is a schematic structural diagram of a display panel according to embodiments of the disclosure.

FIG. 2A is a schematic structural diagram of a pixel circuit according to some embodiments of the disclosure.

FIG. 2B is a timing diagram of signals according to embodiments of the disclosure.

FIG. 3 is a schematic structural diagram illustrating layout of a display panel according to some embodiments of the disclosure.

FIG. 4A is a schematic structural diagram illustrating layout of an active semiconductor layer according to embodiments of the disclosure.

FIG. 4B is a schematic structural diagram illustrating layout of a first conductive layer according to embodiments of the disclosure.

FIG. 4C is a schematic structural diagram illustrating layout of a second conductive layer according to embodiments of the disclosure.

FIG. 4D is a schematic structural diagram illustrating layout of a third conductive layer according to embodiments of the disclosure.

FIG. 4E is a schematic structural diagram illustrating layout of a fourth conductive layer according to embodiments of the disclosure.

FIG. 5A is a schematic structural diagram illustrating laminated layout of an active semiconductor layer and a first conductive layer according to embodiments of the disclosure.

FIG. 5B is a schematic structural diagram illustrating laminated layout of an active semiconductor layer, a first conductive layer and a second conductive layer according to embodiments of the disclosure.

FIG. 5C is a schematic structural diagram illustrating laminated layout of an active semiconductor layer, a first conductive layer, a second conductive layer and a third conductive layer according to embodiments of the disclosure.

FIG. 6 is a schematic structural diagram illustrating layout of another display panel according to some embodiments of the disclosure.

FIG. 7A is a schematic structural diagram illustrating layout of a first electrode layer according to embodiments of the disclosure.

FIG. 7B is a schematic structural diagram illustrating layout of a light emitting layer according to embodiments of the disclosure.

FIG. 8 is a schematic structural diagram illustrating laminated layout of a fourth conductive layer, a first electrode layer and a light emitting layer according to embodiments of the disclosure.

### DETAILED DESCRIPTION

For making objectives, technical solutions and advantages of embodiments of the disclosure clearer, the technical solutions of the embodiments of the disclosure will be clearly and completely described below in conjunction with the accompanying drawings in the embodiments of the disclosure. Apparently, the embodiments described are some embodiments rather than all embodiments of the disclosure. The embodiments in the present disclosure and features of the embodiments can be combined with each other without conflict. Based on the embodiments of the disclosure, all other embodiments obtained by those of ordinary skill in the art without making creative efforts fall within the scope of protection of the disclosure.

Unless otherwise indicated, technical or scientific terms used in the present disclosure should have ordinary meanings as understood by those of ordinary skill in the art to which the present disclosure belongs. “First”, “second”, and other similar words used in the present disclosure do not indicate any order, amount or importance, but are only used to distinguish different components. “Include”, “comprise”, and other similar words indicate that elements or objects before the word include elements or objects after the word and their equivalents, without excluding other elements or objects. “Connection”, “connected”, and other similar words are not limited to physical or mechanical connections, but can include electrical connections, which can be direct or indirect.

It should be noted that a size and a shape of each figure in the drawings do not reflect a true scale, but only for illustrating the present disclosure. Throughout the drawings, identical or similar reference numerals denote identical or similar elements or elements having identical or similar functions.

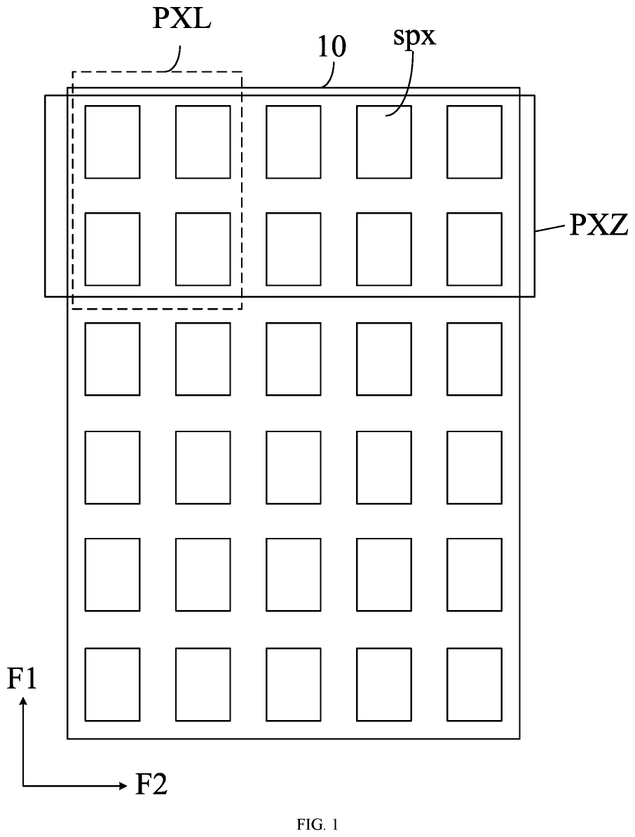

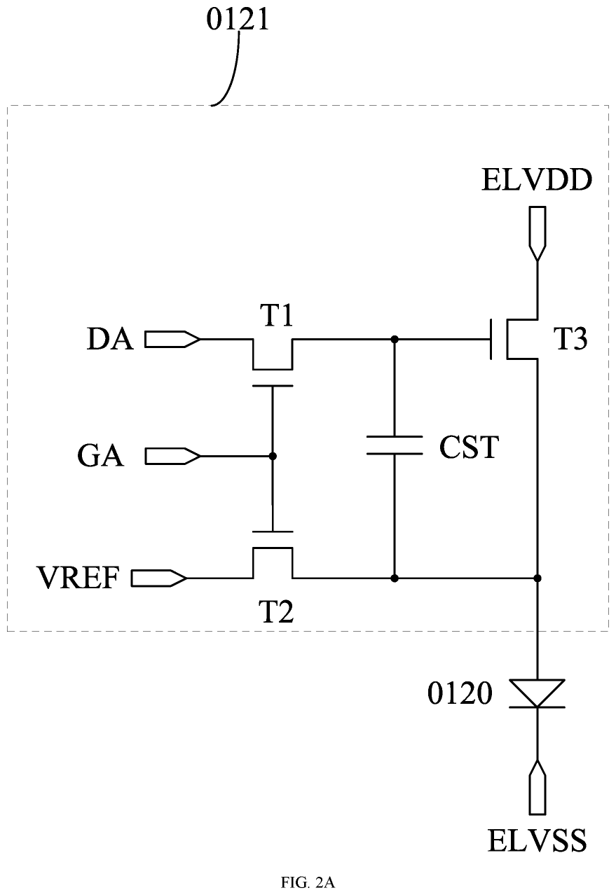

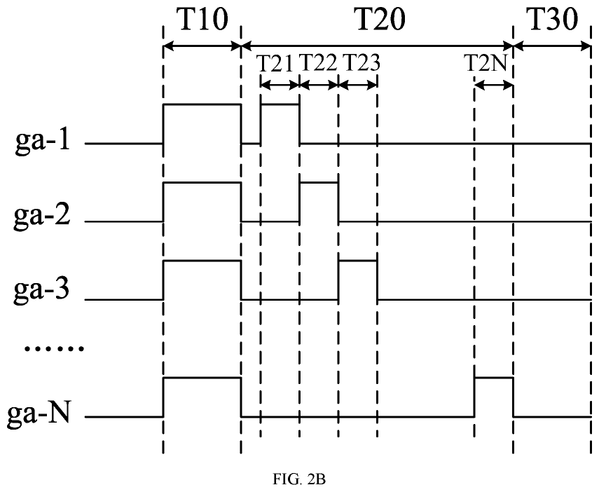

As shown in FIG. 1, a display panel provided in an embodiment of the disclosure may include: a substrate 10. The substrate 10 includes a plurality of sub-pixels spx; For example, as shown in FIGS. 1 and 2A, each sub-pixel spx may include: a pixel circuit 0121 and alight emitting element 0120. The pixel circuit 0121 has a transistor and a capacitor, and generates an electrical signal through interaction between the transistor and the capacitor, and the generated electrical signal is input to an anode of the light emitting element 0120. In addition, a corresponding voltage is applied to a cathode of the light emitting element 0120, such that the light emitting element 0120 may be driven to emit light.

In some embodiments, the sub-pixels may be arranged in an array on the substrate. In this way, the plurality of sub-pixels may be arranged in a first direction F1 and a second direction F2 intersecting with the first direction respectively. For example, the first direction F1 may be a column direction and the second direction F2 may be a row direction. Alternatively, the first direction F1 may be a row direction and the second direction F2 may be a column direction. The following is described by taking the first direction F1 being the column direction and the second direction F2 being the row direction as examples.

In some embodiments, as shown in FIG. 2A, the pixel circuit 0121 includes: a driving transistor T3, a data writing transistor T1, a reset transistor T2, and a storage capacitor CST.

A first electrode of the driving transistor T3 is electrically connected with a power line ELVDD, and a second electrode of the driving transistor T3 is electrically connected with a light emitting element.

A first conductive plate CC1 of the storage capacitor CST is electrically connected with a gate of the driving transistor T3, and a second conductive plate CC2 of the storage capacitor CST is electrically connected with the second electrode of the driving transistor T3.

A gate of the data writing transistor T1 is electrically connected with a scanning line GA, a first electrode of the data writing transistor T1 is electrically connected with a data line DA, and a second electrode of the data writing transistor T1 is electrically connected with the gate of the driving transistor T3.

A gate of the reset transistor T2 is electrically connected with the scanning line GA, a first electrode of the reset transistor T2 is electrically connected with a reset line VREF, and a second electrode of the reset transistor T2 is electrically connected with the second electrode of the driving transistor T3.

The light emitting element 0120 may be set as an electroluminescent diode, for example, an organic light emitting diode (OLED), a quantum dot light emitting diode (QLED), a micro light emitting diode (micro LED), or a mini light emitting diode (Mini OLED). The light emitting element 0120 may include an anode, a light emitting layer and a cathode that are laminated. Furthermore, the light emitting layer may further include a hole injection layer, a hole transport layer, an electron transport layer, an electron injection layer, or other film layers. Certainly, in practical application, the light emitting element 0120 may be designed and determined according to an actual application environment requirement, which is not limited herein.

For example, the power line ELVDD may transmit a first voltage which is constant, and for example, the first voltage is a positive voltage; and an ELVSS terminal connected with the cathode of the light emitting element 0120 may output a second voltage which is constant, and for example, the second voltage is 0 or a negative voltage. For example, the ELVSS terminal may be grounded in some embodiments.

For example, in the transistor, a first electrode may be a source, and a second electrode may be a drain. Alternatively, in the transistor, a first electrode may be a drain, and a second electrode may be a source, which are not limited herein.

In some embodiments, a driving method for the display panel provided in an embodiment of the disclosure may include the following steps.

In a reset stage, a turn-on control signal is applied to each scanning line, a reset signal is applied to each reset line simultaneously, and an initialization signal is applied to each data line simultaneously, so as to initialize a gate of each driving transistor and reset each light emitting element simultaneously.

In a data writing stage, turn-on control signals are applied successively to the scanning lines and the reset signals are applied successively to the reset lines, and corresponding data signals are applied to the data lines while the turn-on control signals are applied to the scanning lines, so as to input the data signal to the gate of each driving transistor.

In a light emitting stage, a turn-off control signal is applied to each scanning line simultaneously, and each driving transistor generates a driving current, so as to drive the light emitting element electrically connected with the driving transistor to emit light.

The above-mentioned driving method will be illustrated through embodiments below. A timing diagram of signals corresponding to a pixel circuit shown in FIG. 2A is as shown in FIG. 2B. In one frame of display time, a working process of a pixel circuit in a display panel may have three stages: a T10 stage, a T20 stage, and a T30 stage. ga-1 represents a signal transmitted on a scanning line GA electrically connected with a pixel circuit in a first row of sub-pixels, ga-2 represents a signal transmitted on a scanning line GA electrically connected with a pixel circuit in a second row of sub-pixels, ga-3 represents a signal transmitted on a scanning line GA electrically connected with a pixel circuit in a third row of sub-pixels, and ga-N represents a signal transmitted on a scanning line GA electrically connected with a pixel circuit in an Nth row of sub-pixels. Here, N is the total row number of sub-pixels.

In the T10 stage, that is, a reset stage, a turn-on control signal is applied to each scanning line GA simultaneously, a reset signal is applied to each reset line VREF simultaneously, and an initialization signal is applied to each data line DA simultaneously, so as to initialize a gate of each driving transistor T3 simultaneously and reset each light emitting element simultaneously. Specifically, if the signal transmitted on each scanning line GA is a high level signal (that is, a turn-on control signal), data writing transistors T1 and reset transistors T2 in the first row of sub-pixels to the Nth row of sub-pixels are all turned on. With one sub-pixel as an example, in the one sub-pixel, the active data writing transistor T1 inputs an initialization signal applied to a data line DA to a gate of a driving transistor T3, so as to initialize the gate of the driving transistor T3. The active reset transistor T2 inputs a reset signal applied to a reset line VREF to an anode of a light emitting element, so as to reset the anode of the light emitting element. A working process of remaining sub-pixels is the same as the above process, which is not repeated herein.

In the T20 stage, that is, a data writing stage, turn-on control signals are applied to the scanning lines GA successively, the reset signals are applied to the reset lines VREF successively, and corresponding data signals are applied to the data lines DA while the turn-on control signals are applied to the scanning lines GA, so as to input the data signal to the gate of each driving transistor T3. Specifically, the T20 stage may include: a T21 stage, a T22 stage, a T23 stage . . . a T2N stage that occur in sequence.

In the T21 stage, the signal ga-1 transmitted on the scanning line GA electrically connected with the pixel circuit in the first row of sub-pixels is the high level signal (that is, the turn-on control signal), and the signals ga-2 to ga-N transmitted on the scanning lines GA electrically connected with the pixel circuits in the second row of sub-pixels to the Nth row of sub-pixels are all low level signals (that is, turn-off control signals), the data writing transistor T1 and the reset transistor T2 in the first row of sub-pixels are both turned on, and the data writing transistors T1 and the reset transistors T2 in the second row of sub-pixels to the Nth row of sub-pixels are all turned off. With one sub-pixel in the first row of sub-pixels as an example, in the sub-pixel, the active data writing transistor T1 inputs a data signal applied to a data line DA to a gate of a driving transistor T3, such that a voltage of the gate of the driving transistor T3 is a voltage Vda1 of the data signal. The active reset transistor T2 inputs a reset signal applied to a reset line VREF to an anode of a light emitting element, so as to reset the anode of the light emitting element.

In the T22 stage, the signal ga-2 transmitted on the scanning line GA electrically connected with the pixel circuit in the second row of sub-pixels is the high level signal (that is, the turn-on control signal), and the signals ga-1, and ga-3 to ga-N transmitted on the scanning lines GA electrically connected with the pixel circuits in the first row of sub-pixels and the third row of sub-pixels to the Nth row of sub-pixels are all low level signals (that is, turn-off control signals), the data writing transistor T1 and the reset transistor T2 in the second row of sub-pixels are both turned on, and the data writing transistors T1 and the reset transistors T2 in the first row of sub-pixels and the third row of sub-pixels to the Nth row of sub-pixels are all turned off. With one sub-pixel in the second row of sub-pixels as an example, in the sub-pixel, the active data writing transistor T1 inputs a data signal applied to a data line DA to a gate of a driving transistor T3, such that a voltage of the gate of the driving transistor T3 is a voltage Vda2 of the data signal. The active reset transistor T2 inputs a reset signal applied to a reset line VREF to an anode of a light emitting element, so as to reset the anode of the light emitting element.

In the T23 stage, the signal ga-3 transmitted on the scanning line GA electrically connected with the pixel circuit in the third row of sub-pixels is the high level signal (that is, the turn-on control signal), and the signals ga-1, ga-2 and ga-4 to ga-N transmitted on the scanning lines GA electrically connected with the pixel circuits in the first row of sub-pixels, the second row of sub-pixels and a fourth row of sub-pixels to the Nth row of sub-pixels are all low level signals (that is, turn-off control signals), the data writing transistor T1 and the reset transistor T2 in the third row of sub-pixels are both turned on, and the data writing transistors T1 and the reset transistors T2 in the first row of sub-pixels, the second row of sub-pixels and the fourth row of sub-pixels to the Nth row of sub-pixels are all turned off. With one sub-pixel in the third row of sub-pixels as an example, in the sub-pixel, the active data writing transistor T1 inputs a data signal applied to a data line DA to a gate of a driving transistor T3, such that a voltage of the gate of the driving transistor T3 is a voltage Vda3 of the data signal. The active reset transistor T2 inputs a reset signal applied to a reset line VREF to an anode of a light emitting element, so as to reset the anode of the light emitting element.

Moreover, working processes of pixel circuits from the fourth row of sub-pixels to the Nth row of sub-pixels are the same as the above process, which are not repeated herein.

In the T2N stage, the signal ga-N transmitted on the scanning line GA electrically connected with the pixel circuit in the Nth row of sub-pixels is the high level signal (that is, the turn-on control signal), and the signals ga-1 to ga-N−1 transmitted on the scanning lines GA electrically connected with the pixel circuits in the first row of sub-pixels to the (N−1)th row of sub-pixels are all low level signals (that is, turn-off control signals), the data writing transistor T1 and the reset transistor T2 in the Nth row of sub-pixels are both turned on, and the data writing transistors T1 and the reset transistors T2 in the first row of sub-pixels to the (N−1)th row of sub-pixels are all turned off. With one sub-pixel in the Nth row of sub-pixels as an example, in the sub-pixel, the active data writing transistor T1 inputs a data signal applied to a data line DA to a gate of a driving transistor T3, such that a voltage of the gate of the driving transistor T3 is a voltage VdaN of the data signal. The active reset transistor T2 inputs a reset signal applied to a reset line VREF to an anode of a light emitting element, so as to reset the anode of the light emitting element.

In the T30 stage, that is, alight emitting stage, a turn-off control signal is applied to each scanning line GA simultaneously, and each driving transistor T3 generates a driving current, so as to drive the light emitting element electrically connected with the driving transistor to emit light. Specifically, if the signal transmitted on each scanning line GA is a low level signal (that is, a turn-off control signal), data writing transistors T1 and reset transistors T2 in the first row of sub-pixels to the Nth row of sub-pixels are all turned off. With one sub-pixel in the first row of sub-pixels as an example, in the sub-pixel, a voltage of a gate of a driving transistor T3 is Vda1, and a voltage of a first electrode of the driving transistor T3 is a voltage Vdd transmitted on a power line ELVDD, such that the driving transistor T3 generates a driving current Ids, and Ids=K(Vdd−Vda1−Vth)2. The driving current Ids is input to a light emitting element, so as to drive the light emitting element to emit light. A working process of pixel circuits in remaining sub-pixels is the same as the above process, which is not repeated herein.

For example, the display panel includes a substrate 10, a transistor array layer on the substrate 10, a planarization layer on a side of the transistor array layer facing away from the substrate 10, a first electrode layer on a side of the planarization layer facing away from the substrate, a light emitting layer on a side of the first electrode layer facing away from the substrate 10, and a cathode on a side of the light emitting layer facing away from the substrate 10. The transistor array layer may include a pixel circuit in each sub-pixel, that is, the transistor array layer may be configured to form a transistor(s) and a capacitor in the pixel circuit, and to form a scanning line GA, a reset line VREF, a power line ELVDD, etc. For example, the transistor array layer may include an active semiconductor layer 0310, a gate insulating layer, a first conductive layer 0320, an interlayer dielectric layer, a second conductive layer 0330, a first interlayer insulating layer, a third conductive layer 0340, a second interlayer insulating layer, and a fourth conductive layer 0350.

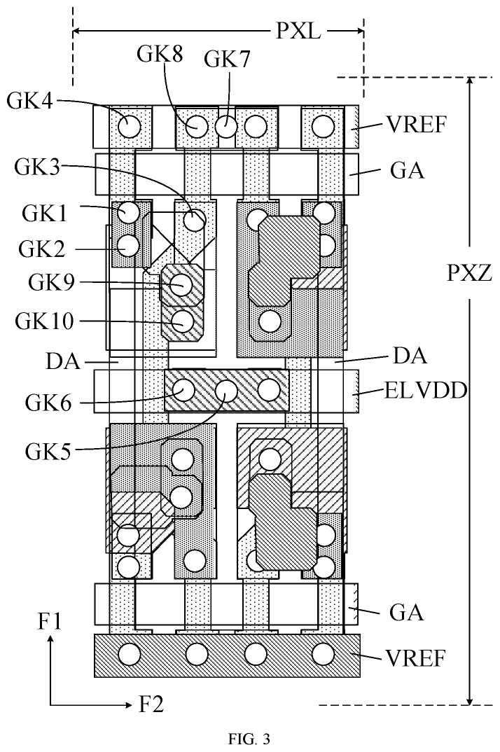

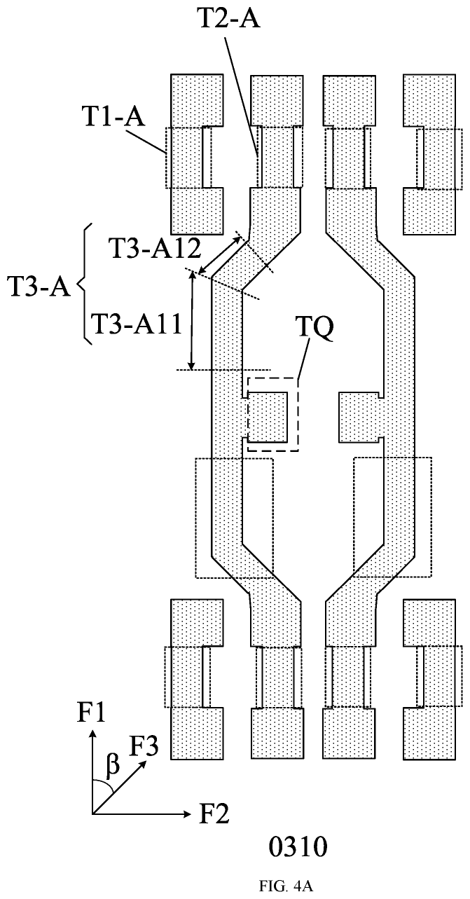

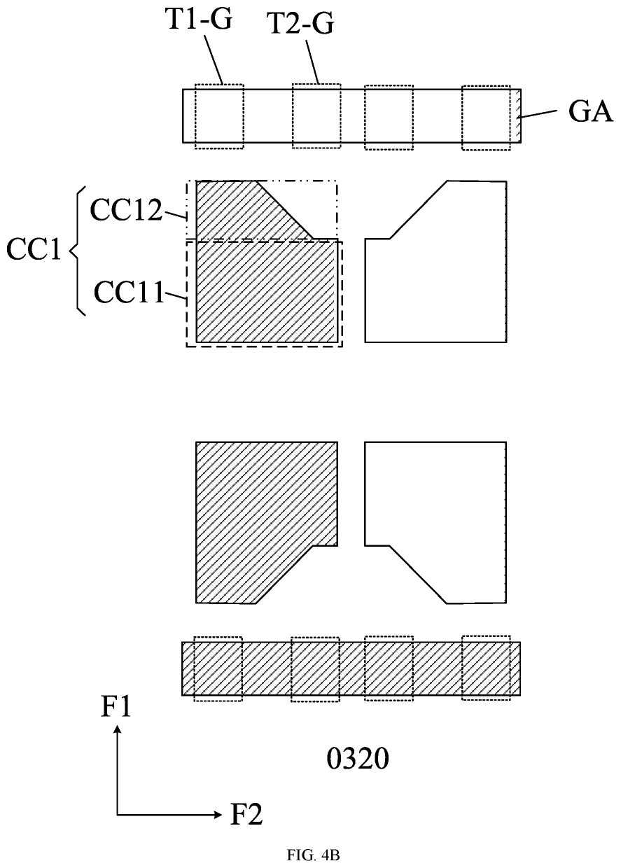

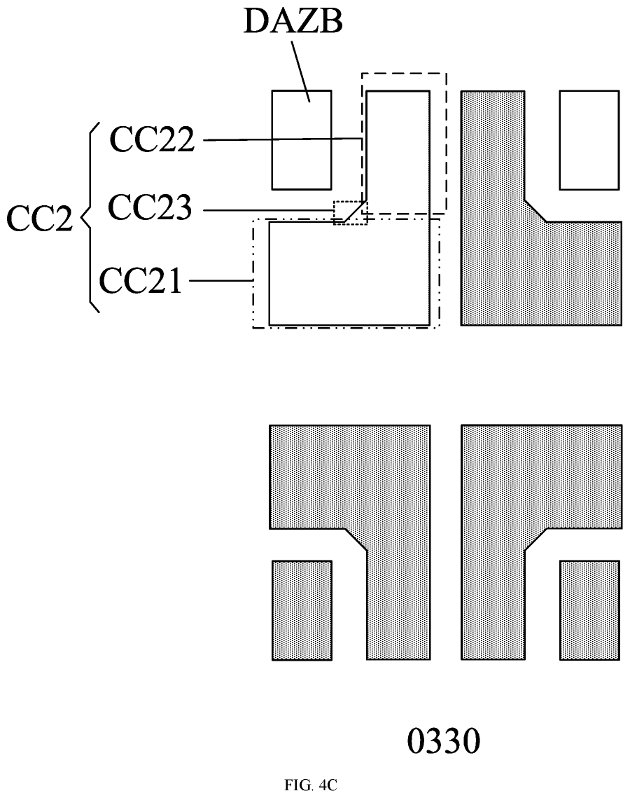

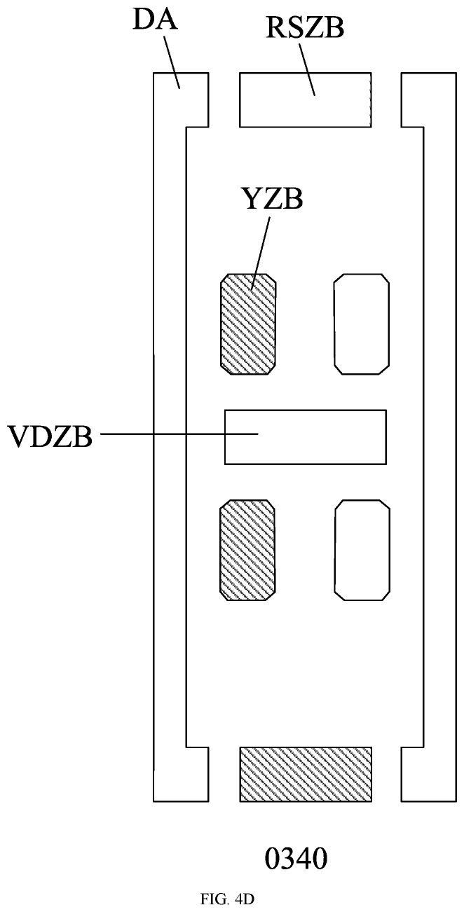

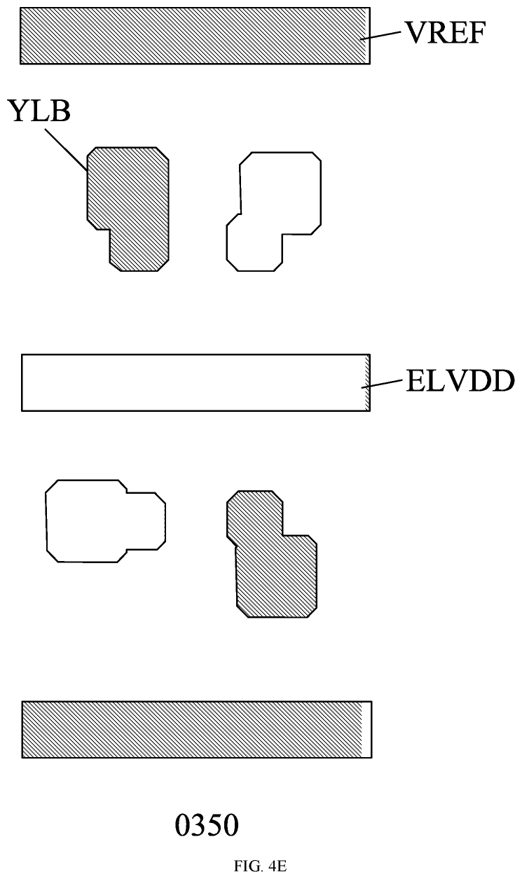

For example, FIGS. 3 and 4A show the active semiconductor layer 0310 of the pixel circuit 0121. The active semiconductor layer 0310 is disposed on the substrate. The active semiconductor layer 0310 may be formed through patterning by using a semiconductor material. For example, the active semiconductor layer 0310 may be configured to form an active zone T3-A of the driving transistor T3, an active zone T1-A of the data writing transistor T1, and an active zone T2-A of the reset transistor T2. Moreover, each active zone may include a conducting source zone, a conducting drain zone, and a channel zone between the conducting source zone and the conducting drain zone.

For example, the active semiconductor layer 0310 may be made of amorphous silicon, polycrystalline silicon, an oxide semiconductor material, etc. It should be noted that the conducting source zone and the conducting drain zone may be conducting zones in which the active semiconductor layer 0310 is doped with n-type impurities or p-type impurities.

For example, as shown in FIGS. 3 and 4A, in one sub-pixel, a channel zone T3-A1 of the active zone of the driving transistor T3 may include a first driving channel zone T3-A11 and a second driving channel zone T3-A12 connected with each other, where the first driving channel zone T3-A11 extends in a first direction F1, the second driving channel zone extends in a third direction F3, and an included angle β between the first direction F1 and the third direction F3 satisfies 0°<β≤90°. For example, β may be equal to 30°, alternatively, β may be equal to 45°, and alternatively, β may be equal to 90°. Certainly, in practical application, a value of the included angle β may be determined according to an actual application requirement, which is not limited herein.

For example, as shown in FIGS. 3 and 4A, the active zone of the reset transistor T2 extends in the first direction F1, and the active zone of the reset transistor T2 is located on an end of the second driving channel zone T3-A12 of the driving transistor T3 facing away from the first driving channel zone T3-A11. In addition, in the same sub-pixel, the conducting drain zone of the active zone of the reset transistor T2 is connected with the second driving channel zone T3-A12 of the driving transistor T3. For example, the active zone of the reset transistor T2 and the active zone of the driving transistor T3 share the conducting drain zone, that is, they are arranged in an integrated structure.

For example, as shown in FIGS. 3 and 4A, the active zone of the data writing transistor T1 is spaced from the active zone of the reset transistor T2 and the active zone of the driving transistor T3 separately, where the active zone of the data writing transistor T1 extends in the first direction F1. In addition, in the same sub-pixel, an orthographic projection of the active zone of the data writing transistor T1 in a second direction F2 is located at a side of an orthographic projection of the second driving channel zone T3-A12 of the driving transistor T3 in the second direction F2 facing away from an orthographic projection of the active zone of the reset transistor T2 in the second direction F2.

For example, as shown in FIGS. 3 and 4A, in the same sub-pixel, a channel zone T1-A1 of the active zone of the data writing transistor T1 and a channel zone T2-A1 of the active zone of the reset transistor T2 are arranged in the second direction F2. Furthermore, in a row of the sub-pixels, the channel zones T1-A1 of the active zones of the data writing transistors T1 and the channel zones T2-A1 of the active zones of the reset transistors T2 are arranged in the second direction F2.

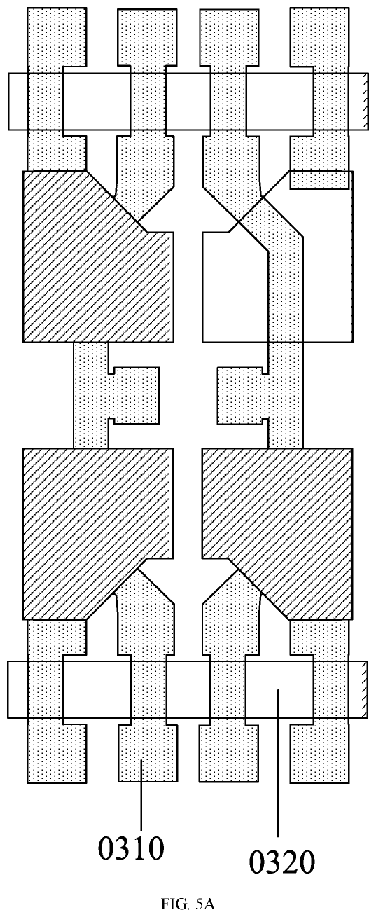

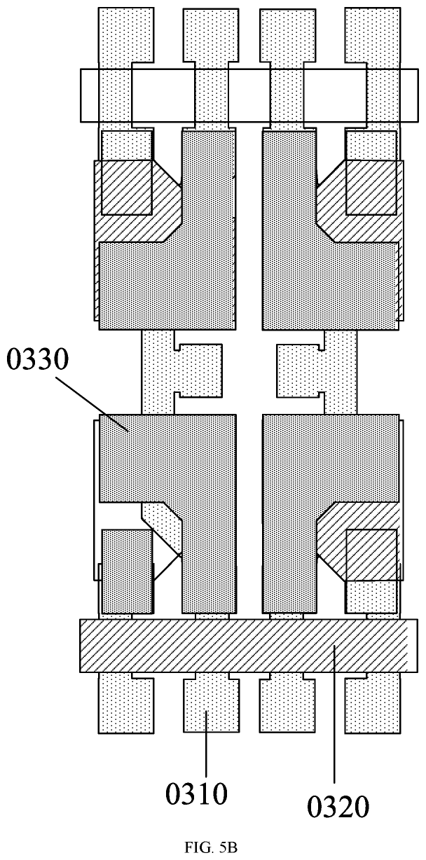

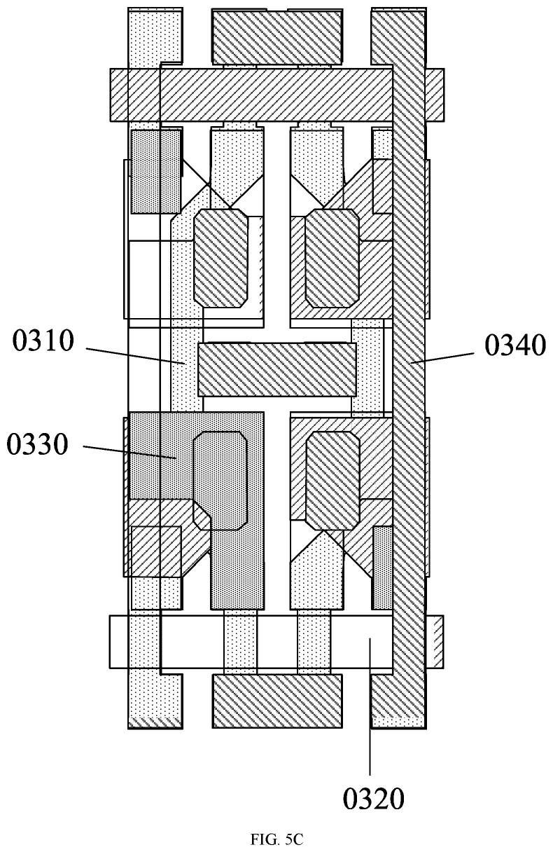

For example, the gate insulating layer is formed on the active semiconductor layer 0310, so as to protect the active semiconductor layer 0310. That is, the gate insulating layer is formed on a side of the active semiconductor layer facing away from the substrate. FIGS. 3, 4B and 5A show the first conductive layer 0320 of the pixel circuit 0121. The first conductive layer 0320 is disposed on a side of a gate insulating layer facing away from a substrate 10, so as to be insulated from the active semiconductor layer 0310. The first conductive layer 0320 may include a first conductive plate CC1 of a storage capacitor CST, a plurality of scanning lines GA that are spaced from each other, a gate T1-G of a data writing transistor T1, and a gate T2-G of a reset transistor T2.

For example, as shown in FIGS. 3, 4B and 5A, the gate T1-G of the data writing transistor T1 may be a first part of the scanning line GA overlapping the active semiconductor layer 0310, and the gate T2-G of the reset transistor T2 may be a second part of the scanning line GA overlapping the active semiconductor layer 0310. The first conductive plate CC1 of the storage capacitor CST is reused as a gate of a driving transistor T3.

It should be noted that dotted lines in FIGS. 4A and 4B show the respective overlapping parts of the first conductive layer 0320 and the active semiconductor layer 0310.

For example, as shown in FIGS. 3 and 4B, pixel circuits in one row of the sub-pixels are electrically connected with one scanning line GA correspondingly. The scanning line GA is arranged in a first direction F1. Meanwhile, the scanning line GA extends in a second direction F2. In the first direction F1, the first conductive plate CC1 of the storage capacitor CST is located between two adjacent scanning lines GA.

For example, as shown in FIGS. 3, 4B and 5A, in each sub-pixel, an orthographic projection of the first conductive plate CC1 of the storage capacitor CST on the substrate has an overlapping region with an orthographic projection of a channel zone T3-A1 of an active zone of the driving transistor T3 on the substrate 10. Furthermore, in each sub-pixel, the orthographic projection of the first conductive plate CC1 of the storage capacitor CST on the substrate 10 has an overlapping region with each of orthographic projections of a first driving channel zone channel T3-A11 and a second driving channel zone T3-A12 of the driving transistor T3 on the substrate 10.

For example, as shown in FIGS. 3, 4B and 5A, in the same sub-pixel, an orthographic projection of the scanning line GA on the substrate 10 has an overlapping region with each of a channel zone T1-A1 of an active zone of the data writing transistor T1 and a channel zone T2-A1 of an active zone of the reset transistor T2. In this way, the first part of the scanning line GA is used as a gate of the data writing transistor T1, and the second part of the scanning line GA is used as a gate of the reset transistor T2.

For example, the interlayer dielectric layer is formed on the first conductive layer 0320, so as to protect the first conductive layer 0320. That is, the interlayer dielectric layer is formed on a side of the first conductive layer 0320 facing away from the substrate 10. The second conductive layer 0330 is formed on a side of the interlayer dielectric layer facing away from the substrate 10. FIGS. 3, 4C and 5B show the second conductive layer 0330 of the pixel circuit 120a. The second conductive layer 0330 includes a second conductive plate CC2 of the storage capacitor CST and a data adaptor part DAZB. One sub-pixel includes a second conductive plate CC2 of one storage capacitor CST and one data adaptor part DAZB.

For example, as shown in FIGS. 3, 4B and 5B, the first conductive plate CC1 of the storage capacitor CST may include a first conductive plate body part CC11 and a first conductive plate protrusion part CC12 electrically connected with each other, that is, the first conductive plate body part CC11 and the first conductive plate protrusion part CC12 are integrated into the first conductive plate CC1 of the storage capacitor CST. In addition, in the same sub-pixel, a first end of the data adaptor part DAZB is electrically connected with a conducting drain zone of the active zone of the data writing transistor T1 through a first via hole GK1, and a second end of the data adaptor part DAZB is electrically connected with the first conductive plate protrusion part CC12 through a second via hole GK2, where the first via hole GK1 runs through the gate insulating layer and the interlayer dielectric layer, and the second via hole GK2 runs through the interlayer dielectric layer. In this way, the conducting drain zone of the active zone of the data writing transistor T1 is connected with the first conductive plate CC1 of the storage capacitor CST through the data adaptor part DAZB, such that patterning of the gate insulating layer may be avoided, use of a mask may be reduced by one time, and further the process flow and cost may be decreased.

For example, as shown in FIGS. 3, 4C and 5B, the second conductive plate CC2 of the storage capacitor CST may include a second conductive plate body part CC21 and a second conductive plate protrusion part CC22 electrically connected with each other, that is, the second conductive plate body part CC21 and the second conductive plate protrusion part CC22 are integrated into the second conductive plate CC2 of the storage capacitor CST. In addition, in the same sub-pixel, the second conductive plate protrusion part CC22 is electrically connected with the conducting drain zone of the active zone of the reset transistor T2 through a third via hole GK3, where the third via hole GK3 runs through the interlayer dielectric layer and the gate insulating layer.

For example, as shown in FIGS. 3, 4C and 5B, the second conductive plate CC2 of the storage capacitor CST and the first conductive plate CC1 of the storage capacitor CST at least partially overlap to form the storage capacitor CST. Furthermore, in the same sub-pixel, an orthographic projection of the first conductive plate body part CC11 on the substrate 10 has an overlapping region with an orthographic projection of the second conductive plate body part CC21 on the substrate 10.

For example, as shown in FIGS. 3, 4C and 5B, the second conductive plate CC2 of the storage capacitor CST may further include: a second conductive plate compensation part CC23 electrically connected with the second conductive plate body part CC21 and the second conductive plate protrusion part CC22 respectively, where the second conductive plate compensation part CC23 is located at a corner formed by the second conductive plate body part CC21 and the second conductive plate protrusion part CC22. In addition, in the same sub-pixel, an orthographic projection of the second conductive plate compensation part CC23 on the substrate 10 has an overlapping region with the orthographic projection of the first conductive plate body part CC11 on the substrate 10. In this way, an area of the second conductive plate CC2 of the storage capacitor CST may be increased; and further, a capacitance value of the storage capacitor CST may be improved, and storage capacity of the storage capacitor CST may be improved.

For example, as shown in FIGS. 3, 4C and 5B, in the same sub-pixel, the orthographic projection of the first conductive plate body part CC11 on the substrate 10 has an overlapping region with an edge area of an orthographic projection of the second conductive plate protrusion part CC22 on the substrate 10 close to the orthographic projection of the second conductive plate body part CC21 on the substrate 10. In this way, an area of the second conductive plate CC2 of the storage capacitor CST may be further increased; and further, a capacitance value of the storage capacitor CST may be improved, and storage capacity of the storage capacitor CST may be improved.

For example, the first interlayer insulating layer is formed on the second conductive layer 0330, so as to protect the second conductive layer 0330. That is, the first interlayer insulating layer is formed on a side of the second conductive layer 0330 facing away from the substrate 10, and the third conductive layer 0340 is formed on a side of the first interlayer insulating layer facing away from the substrate 10. FIGS. 3, 4D and 5C show the third conductive layer 0340 of the pixel circuit 0121. The third conductive layer 0340 may include a plurality of data lines DA that are spaced from each other, a plurality of reset adaptor parts RSZB that are spaced from each other, a plurality of power adaptor parts VDZB that are spaced from each other, and a plurality of anode adaptor parts YZB that are spaced from each other. There is one anode adaptor part YZB in one sub-pixel.

For example, as shown in FIGS. 3, 4D, and 5C, the data lines DA extend in the first direction F1 and are arranged in the second direction F2. One column of the sub-pixels are electrically connected with one data line DA correspondingly. In the same sub-pixel, the data line DA is electrically connected with a conducting source zone of the active zone of the data writing transistor T1 through a fourth via hole GK4, where the fourth via hole GK4 runs through the first interlayer insulating layer, the interlayer dielectric layer and the gate insulating layer, and an orthographic projection of the fourth via hole GK4 on the substrate 10 is located at a side of the orthographic projection of the scanning line GA on the substrate 10 facing away from the orthographic projection of the first conductive plate CC1 of the storage capacitor CST on the substrate 10.

For example, the second interlayer insulating layer may be further formed on the third conductive layer 0340, so as to protect the third conductive layer 0340. That is, the second interlayer insulating layer is formed on a side of the third conductive layer 0340 facing away from the substrate 10, and the fourth conductive layer 0350 is formed on a side of the second interlayer insulating layer facing away from the substrate 10. FIGS. 3 and 4E show the fourth conductive layer 0350 of the pixel circuit 0121. The fourth conductive layer 0350 may include: a plurality of power lines ELVDD that are spaced from each other, a plurality of reset lines VREF that are spaced from each other, and a plurality of anode connecting parts YLB that are spaced from each other. There is one anode connecting part YLB in one sub-pixel. In addition, in the same sub-pixel, the anode connecting part YLB is electrically connected with a first end of the anode adaptor part YZB through a ninth via hole GK9, and a second end of the anode adaptor part YZB is electrically connected with the second conductive plate CC2 of the storage capacitor CST through a tenth via hole GK10, where the ninth via hole GK9 runs through the second interlayer insulating layer, and the tenth via hole GK10 runs through the first interlayer insulating layer.

For example, as shown in FIGS. 3 and 4E, the scanning lines GA have the same extension direction as the power lines ELVDD, and the reset lines VREF have the same extension direction as the power lines ELVDD. That is, the scanning lines GA, the power lines ELVDD and the reset lines VREF extend in the second direction F2.

For example, as shown in FIGS. 3 and 4E, in the same sub-pixel, an orthographic projection of the ninth via hole GK9 on the substrate 10 and an orthographic projection of the tenth via hole GK10 on the substrate 10 are arranged in the first direction F1.

For example, as shown in FIGS. 3 and 4E, in the same sub-pixel, the orthographic projection of the tenth via hole GK10 on the substrate 10 is located at a side of the orthographic projection of the ninth via hole GK9 on the substrate 10 facing away from an orthographic projection of the third via hole GK3 on the substrate 10.

For example, as shown in FIGS. 3 and 4E, in the same sub-pixel, the orthographic projection of the ninth via hole GK9 on the substrate 10 has an overlapping region with the orthographic projection of the second conductive plate compensation part CC23 on the substrate 10.

For example, as shown in FIGS. 3 and 4E, the power lines ELVDD extend in the second direction F2 and are arranged in the first direction F1. One power line ELVDD corresponds to at least one row of the sub-pixels. For example, one power line ELVDD is electrically connected with pixel circuits in two adjacent rows of sub-pixels.

For example, as shown in FIGS. 3 and 4E, in the same sub-pixel, the power line ELVDD is electrically connected with the power adaptor part VDZB through a fifth via hole GK5, and the power adaptor part VDZB is electrically connected with a conducting source zone of the active zone of the driving transistor T3 through a sixth via hole GK6, where the fifth via hole GK5 runs through the second interlayer insulating layer, and the sixth via hole GK6 runs through the first interlayer insulating layer, the interlayer dielectric layer, and the gate insulating layer.

For example, as shown in FIGS. 1, 3 and 4E, in two adjacent sub-pixels, orthographic projections of pixel circuits on the substrate are arranged in a mirror symmetry manner. For example, as shown in FIGS. 1, 3 and 4E, two adjacent rows of sub-pixels form one row group, and different row groups include different sub-pixels; and two scanning lines corresponding to the row group have a row symmetry axis in a row direction, and orthographic projections of pixel circuits in the sub-pixels of the same row group on the substrate are arranged in a mirror symmetry manner with respect to the row symmetry axis.

For example, as shown in FIGS. 1, 3 and 4E, two adjacent columns of sub-pixels in the same row group form one column group, and different column groups include different sub-pixels; and two data lines corresponding to the column group have a column symmetry axis in a column direction, and orthographic projections of pixel circuits in the same column group of sub-pixels on the substrate are arranged in a mirror symmetry manner with respect to the column symmetry axis.

For example, as shown in FIGS. 1, 3 and 4E, the same row group of sub-pixels share one power line ELVDD. In addition, orthographic projections of pixel circuits located in the same column and at two sides of the power line ELVDD on the substrate 10 are arranged symmetrically with respect to the orthographic projection of the power line ELVDD on the substrate 10. For example, the orthographic projections of the pixel circuits located in the same column and at two sides of the power line ELVDD on the substrate 10 are arranged roughly in a mirror symmetry manner with respect to the orthographic projection of the power line ELVDD on the substrate 10.

For example, as shown in FIGS. 1, 3 and 4A, the active semiconductor layer 0310 further includes a plurality of driving protrusion parts TQ; and conducting source zones of driving transistors T3 in two sub-pixels in the same column of the row group are electrically connected with one driving protrusion part TQ, where in the same driving transistor T3, the conducting source zone is electrically connected with the first driving channel zone T3-A11, and the conducting source zone and the first driving channel zone T3-A11 electrically connected with each other extend in the same direction. In addition, in the same column of the sub-pixels, an orthographic projection of the driving protrusion part TQ on the substrate 10 is located at a side of an orthographic projection of the conducting source zone on the substrate 10 facing away from the orthographic projection of the data line DA on the substrate 10. Furthermore, the power adaptor part VDZB is electrically connected, through the sixth via hole GK6, to the driving protrusion part TQ electrically connected with the driving transistor T3, and an orthographic projection of the driving protrusion part TQ electrically connected with the driving transistor T3 on the substrate 10 covers an orthographic projection of the sixth via hole GK6 on the substrate 10.

For example, as shown in FIGS. 3 and 4A, in the same column of the sub-pixels, an extension line of the active zone of the reset transistor in the column direction (that is, the first direction F1) has an overlapping region with the driving protrusion part TQ. Furthermore, in the same column of the sub-pixels, an extension line of the channel zone T2-A of the reset transistor in the column direction (that is, the first direction F1) has an overlapping region with the driving protrusion part TQ.

For example, as shown in FIGS. 3 and 4D, in the same column of the sub-pixels, an orthographic projection of the fifth via hole GK5 on the substrate 10 is located at a side of the orthographic projection of the sixth via hole GK6 on the substrate 10 facing away from the orthographic projection of the data line DA on the substrate 10.

For example, as shown in FIGS. 1, 3 and 4D, two data lines DA corresponding to the column group have the column symmetry axis in a column direction, and orthographic projections of pixel circuits in the same column group of sub-pixels on the substrate 10 are arranged symmetrically with respect to the symmetry axis.

For example, as shown in FIGS. 1, 3 and 4D, driving transistors T3 in the same column group share one power adaptor part VDZB. In this way, a first voltage input from the driving transistors T3 in the same column group may be more stable.

For example, as shown in FIGS. 3 and 4E, the orthographic projection of the power line ELVDD on the substrate 10 covers an orthographic projection of the power adaptor part VDZB electrically connected with the power line on the substrate 10.

For example, as shown in FIGS. 3 and 4E, the reset lines VREF extend in the second direction F2 and are arranged in the first direction F1. In addition, one reset line VREF corresponds to at least one row of the sub-pixels. For example, one reset line VREF is electrically connected with pixel circuits in two adjacent rows of sub-pixels correspondingly. Furthermore, in the same sub-pixel, the reset line VREF is electrically connected with the reset adaptor part RSZB through a seventh via hole GK7, and the reset adaptor part RSZB is electrically connected with a conducting source zone of the active zone of the reset transistor T2 through an eighth via hole GK8, where the seventh via hole GK7 runs through the second interlayer insulating layer, and the eighth via hole GK8 runs through the first interlayer insulating layer, the interlayer dielectric layer, and the gate insulating layer.

For example, as shown in FIGS. 3 and 4E, two adjacent rows of sub-pixels located in different row groups share one reset line VREF; and orthographic projections of pixel circuits located in the same column and at two sides of the reset line VREF on the substrate are arranged symmetrically with respect to the orthographic projection of the reset line VREF on the substrate 10. For example, the orthographic projections of the pixel circuits located in the same column and at two sides of the reset line VREF on the substrate 10 are arranged roughly in a mirror symmetry manner with respect to the orthographic projection of the reset line VREF on the substrate 10.

For example, as shown in FIGS. 3 and 4E, for two rows of sub-pixels sharing the same reset line VREF, two adjacent columns of sub-pixels in the two rows of sub-pixels share one reset adaptor part RSZB. In this way, uniformity of the reset signals input via the reset transistors T2 in the four sub-pixels may be improved.

For example, as shown in FIGS. 3 and 4E, the orthographic projection of the reset line VREF on the substrate 10 covers an orthographic projection of the reset adaptor part RSZB electrically connected with the reset line on the substrate 10.

For example, as shown in FIGS. 3 and 4D, in the same column of the sub-pixels, an orthographic projection of the seventh via hole GK7 on the substrate 10 is located at one side of an orthographic projection of the eighth via hole GK8 on the substrate 10 facing away from the orthographic projection of the data line DA on the substrate 10.

For example, as shown in FIGS. 3 and 4E, for a power line ELVDD, a scanning line GA and a reset line VREF corresponding to one row of sub-pixel circuits, an orthographic projection of the scanning line GA on the substrate 10 is located between an orthographic projection of the power line ELVDD on the substrate 10 and an orthographic projection of the reset line VREF on the substrate 10.

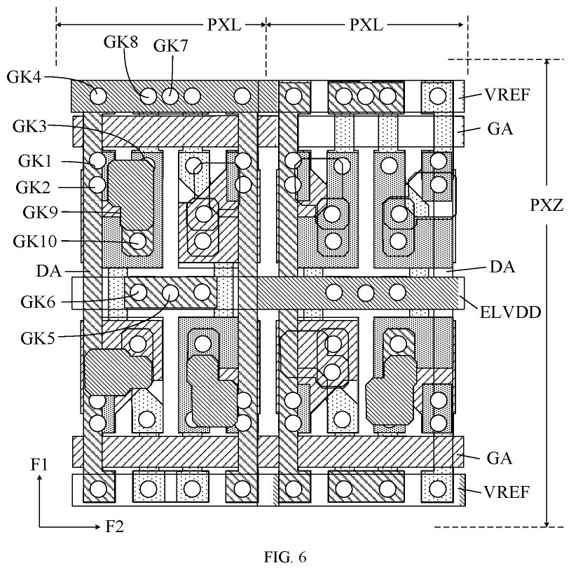

For example, a planarization layer is formed on the fourth conductive layer 0350, so as to protect the fourth conductive layer 0350. For example, as shown in FIGS. 3-8, a first electrode layer 0360 is formed on one side of the planarization layer facing away from the substrate 10. The first electrode layer 0360 includes an anode in each sub-pixel. The anode in each sub-pixel is electrically connected with an anode connecting part YLB through an anode via hole GK0. In addition, the anode in each sub-pixel includes an anode body part and an anode protrusion part electrically connected with each other. In the same anode, the anode body part is electrically connected with the anode protrusion part, and the anode protrusion part is electrically connected with the anode connecting part YLB through the anode via hole GK0. In addition, the anode via hole GK0 runs through the planarization layer. In this way, a driving current generated by the driving transistor T3 may be input into an anode of a light emitting element. For example, the anode protrusion part of each anode is in an irregular shape.

In some embodiments, for example, as shown in FIGS. 3-8, in at least one sub-pixel, an orthographic projection of the anode connecting part YLB on the substrate 10 has an overlapping region with the orthographic projection of the data line DA on the substrate 10. Furthermore, in some sub-pixels, the orthographic projection of the anode connecting part YLB on the substrate 10 has an overlapping region with the orthographic projection of the data line DA on the substrate 10.

In some embodiments, for example, as shown in FIGS. 3-8, in the same sub-pixel, the orthographic projection of the anode connecting part YLB on the substrate 10 has an overlapping region with the orthographic projection of the corner between the first driving channel zone T3-A11 and the second driving channel zone T3-A12 on the substrate 10.

In some embodiments, for example, as shown in FIGS. 3-8, in at least one sub-pixel, an overlapping region between the orthographic projection of the anode connecting part YLB on the substrate 10 and the orthographic projection of the second driving channel zone T3-A12 on the substrate 10 is larger than an overlapping region between the orthographic projection of the anode connecting part YLB on the substrate 10 and the orthographic projection of the first driving channel zone T3-A11 on the substrate. Furthermore, in some sub-pixels, an overlapping region between the orthographic projection of the anode connecting part YLB on the substrate 10 and the orthographic projection of the second driving channel zone T3-A12 on the substrate 10 is larger than an overlapping region between the orthographic projection of the anode connecting part YLB on the substrate 10 and the orthographic projection of the first driving channel zone T3-A11 on the substrate 10.

In some embodiments, for example, as shown in FIGS. 3-8, in the same column of the sub-pixels, the anode connecting parts are arranged in the first direction and are not arranged on the same straight line. In the same row of the sub-pixels, the anode connecting parts are arranged in the first direction and are not arranged on the same straight line.

In some embodiments, for example, as shown in FIGS. 3-8, in the same sub-pixel, an orthographic projection of a part of the anode adaptor part YZB close to the ninth via hole GK9 on the substrate 10 has an overlapping region with the orthographic projection of the corner between the first driving channel zone T3-A11 and the second driving channel zone T3-A12 on the substrate 10.

In some embodiments, for example, as shown in FIGS. 3-8, in the same column of the sub-pixels, the anode adaptor parts are arranged on the same straight line in the first direction. In the same row of the sub-pixels, the anode adaptor parts are arranged on the same straight line in the second direction.

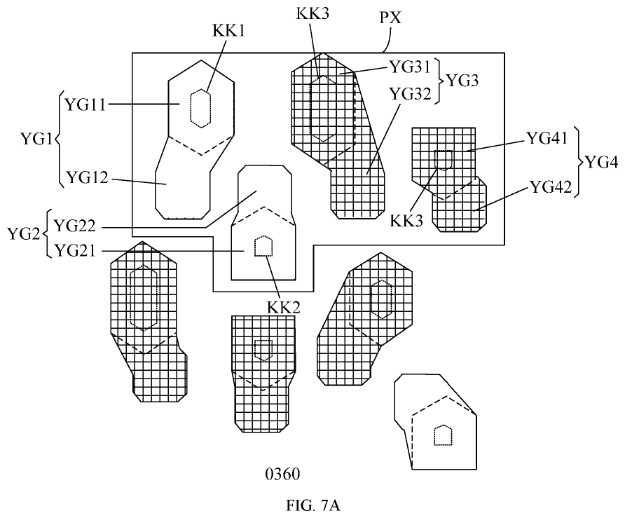

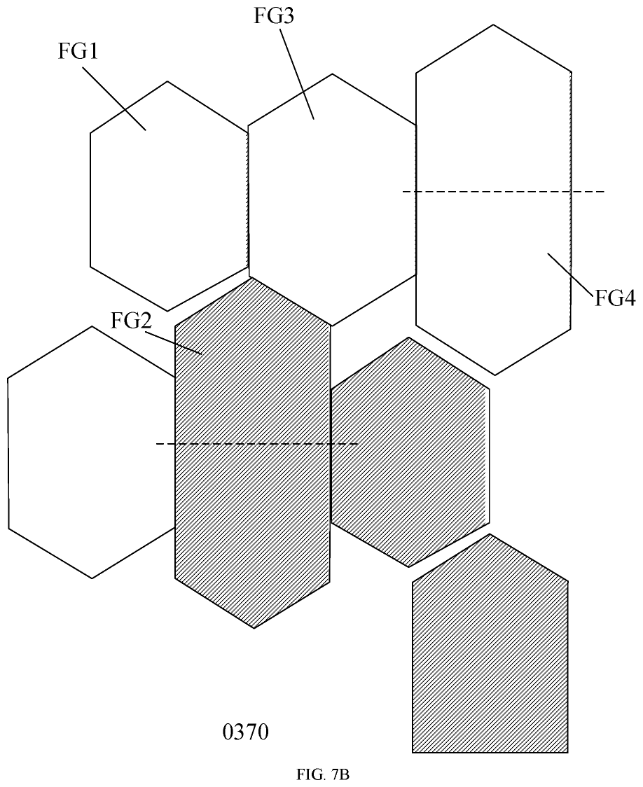

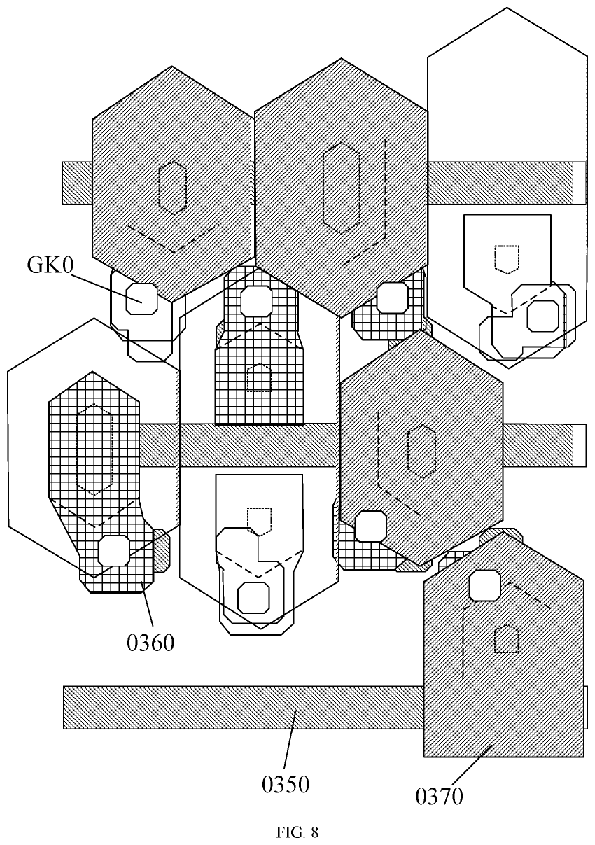

In some embodiments, a side of the first electrode layer facing away from the substrate is further provided with a pixel defining layer, and a side of the pixel defining layer facing away from the substrate is further provided with a light emitting layer, and a side of the light emitting layer facing away from the substrate is further provided with a cathode layer. In this way, the anode, the light emitting layer and the cathode may constitute a light emitting element. For example, as shown in FIGS. 7A and 8, the pixel defining layer may include a plurality of opening regions (such as KK1, KK2, KK3, and KK4). One anode corresponds to one opening region, and an orthographic projection of the opening region on the substrate 10 is located within an orthographic projection of an anode body part of the corresponding anode on the substrate 10. The light emitting layers include a plurality of light emitting layers with different colors (such as FG1, FG2, and FG0).

For example, as shown in FIGS. 7A and 8, in each sub-pixel, the orthographic projection of the opening region (such as KK1, KK2, KK3, and KK4) on the substrate has no overlapping region with an orthographic projection of an anode via hole GK0 on the substrate.

For example, as shown in FIGS. 7A and 8, the orthographic projection of the power line on the substrate passes through orthographic projections of opening regions in at least two sub-pixels on the substrate. In this way, the anodes in the opening regions of the sub-pixels may be as planar as possible, and color uniformity may be improved.

For example, as shown in FIGS. 3 and 6-8, first signal lines may be data lines, and second signal lines may be power lines. Alternatively, first signal lines may be data lines, and second signal lines may be power lines. Alternatively, first signal lines may be data lines, and the third conductive layer may include power lines. Alternatively, second signal lines may be power lines, and the fourth conductive layer may include data lines. Certainly, in practical application, the first signal lines and the second signal lines may be designed and determined according to an actual application requirement, which are not limited herein.

For example, a plurality of sub-pixels in the display panel may constitute a plurality of repeating units. For example, the repeating unit may include four sub-pixels adjacent in the second direction F2. A structure of a pixel circuit in each sub-pixel may be set with reference to the above description. For example, four sub-pixels in the repeating unit may include a first sub-pixel, a second sub-pixel, a third sub-pixel and a fourth sub-pixel in the second direction F2. A light emitting element in the first sub-pixel may emit red light, a light emitting element in the second sub-pixel may emit green light, a light emitting element in the third sub-pixel may emit blue light, and a light emitting element in the fourth sub-pixel may emit green light. Furthermore, in two adjacent rows, the repeating units are staggered. For example, for two adjacent repeating units in different rows, an anode of a second sub-pixel in one of the two repeating units and an anode of a fourth sub-pixel in the other repeating unit are arranged in the first direction F1.

For example, as shown in FIGS. 3 and 6-8, the first sub-pixel may include an anode YG1. The anode YG1 may include an anode body part YG11 and an anode protrusion part YG12. In addition, an orthographic projection of an opening region KK1 on the substrate 10 is located within an orthographic projection of the anode body part YG11 on the substrate 10. The anode body part YG11 is hexagonal, and the anode protrusion part YG12 is in an irregular shape. The anode protrusion part YG12 protrudes from a left bottom of the anode body part YG11. Furthermore, the first sub-pixel may include a light emitting layer FG1, and an orthographic projection of the light emitting layer FG1 on the substrate 10 covers the orthographic projection of the anode body part YG11 on the substrate 10. For example, the anode body part YG11 may also be quadrangular, pentagonal, hexagonal, octagonal, etc., which is not limited herein. The opening region KK1 may also be quadrangular, pentagonal, hexagonal, octagonal, etc., which is not limited herein.

For example, as shown in FIGS. 3 and 6-8, the second sub-pixel may include an anode YG2. The anode YG2 may include an anode body part YG21 and an anode protrusion part YG22. In addition, an orthographic projection of an opening region KK2 on the substrate 10 is located within an orthographic projection of the anode body part YG21 on the substrate 10. The anode body part YG21 is pentagonal, and the anode protrusion part YG22 is in an irregular shape. The anode protrusion part YG22 protrudes from the anode body part YG21 in a direction indicated by an arrow of the first direction F1. Furthermore, the second sub-pixel may include a light emitting layer FG2, and an orthographic projection of the light emitting layer FG2 on the substrate 10 covers the orthographic projection of the anode body part YG21 on the substrate 10. For example, the anode body part YG21 may also be quadrangular, pentagonal, hexagonal, octagonal, etc., which is not limited herein. The opening region KK2 may also be quadrangular, pentagonal, hexagonal, octagonal, etc., which is not limited herein.

For example, as shown in FIGS. 3 and 6-8, the third sub-pixel may include an anode YG3. The anode YG3 may include an anode body part YG31 and an anode protrusion part YG32. In addition, an orthographic projection of an opening region KK3 on the substrate 10 is located within an orthographic projection of the anode body part YG31 on the substrate 10. The anode body part YG31 is hexagonal, and the anode protrusion part YG32 is in an irregular shape. The anode protrusion part YG32 protrudes from a right bottom of the anode body part YG31. Furthermore, the third sub-pixel may include a light emitting layer FG3, and an orthographic projection of the light emitting layer FG3 on the substrate 10 covers the orthographic projection of the anode body part YG31 on the substrate 10. For example, the anode body part YG31 may also be quadrangular, pentagonal, hexagonal, octagonal, etc., which is not limited herein. The opening region KK3 may also be quadrangular, pentagonal, hexagonal, octagonal, etc., which is not limited herein.

For example, as shown in FIGS. 3 and 6-8, the fourth sub-pixel may include an anode YG4. The anode YG4 may include an anode body part YG41 and an anode protrusion part YG42. In addition, an orthographic projection of an opening region KK4 on the substrate 10 is located within an orthographic projection of the anode body part YG41 on the substrate 10. The anode body part YG41 is pentagonal, and the anode protrusion part YG42 is in an irregular shape. The anode protrusion part YG42 protrudes from the anode body part YG41 in a direction opposite to a direction indicated by an arrow of the first direction F1. Furthermore, the fourth sub-pixel may include a light emitting layer FG4, and an orthographic projection of the light emitting layer FG4 on the substrate 10 covers the orthographic projection of the anode body part YG41 on the substrate 10. For example, the anode body part YG41 may also be quadrangular, pentagonal, hexagonal, octagonal, etc., which is not limited herein. The opening region KK4 may also be quadrangular, pentagonal, hexagonal, octagonal, etc., which is not limited herein.

For example, as shown in FIGS. 3 and 6-8, in the case that two adjacent repeating units in different rows are arranged in the first direction F1, an anode of a second sub-pixel in one of the two repeating units and an anode of a fourth sub-pixel in the other repeating unit are arranged in the first direction F1. In addition, a light emitting layer covering an anode body part of the anode of the second sub-pixel and a light emitting layer covering an anode body part of the anode of the fourth sub-pixel are integrated. In this way, mask difficulty may be reduced.

In some embodiments, as shown in FIGS. 3-8, a data signal on the data line DA is transmitted to the conducting source zone of the active zone of the data writing transistor T1 through the fourth via hole GK4; the data signal transmitted to the conducting source zone of the active zone of the data writing transistor T1 is transmitted to the conducting drain zone of the active zone of the data writing transistor T1 through the channel zone of the active zone of the data writing transistor T1; the data signal transmitted to the conducting drain zone of the active zone of the data writing transistor T1 is transmitted to the data adaptor part DAZB through the first via hole GK1; and the data signal transmitted to the data adaptor part DAZB is transmitted to the first conductive plate CC1 of the storage capacitor CST through the second via hole GK2.

In some embodiments, as shown in FIGS. 3-8, a reset signal on the reset line VREF is transmitted to the conducting source zone of the active zone of the reset transistor T2 through the eighth via hole GK8; the reset signal transmitted to the conducting source zone of the active zone of the reset transistor T2 is transmitted to the conducting drain zone of the active zone of the reset transistor T2 through the channel zone of the active zone of the reset transistor T2; the reset signal transmitted to the conducting drain zone of the active zone of the reset transistor T2 is transmitted to the second conductive plate CC2 of the storage capacitor CST through the third via hole GK3; the reset signal transmitted to the second conductive plate CC2 of the storage capacitor CST is transmitted to the anode adaptor part YZB through the tenth via hole GK10; and the reset signal transmitted to the anode adaptor part YZB is transmitted to the anode connecting part YLB through the ninth via hole GK9.

In some embodiments, as shown in FIGS. 3-8, a power signal on the power line ELVDD is transmitted to the power adaptor part VDZB through the fifth via hole GK5; and the power signal transmitted to the power adaptor part VDZB is transmitted, through the sixth via hole GK6, to the driving protrusion part TQ electrically connected with the driving transistor T3.

In some embodiments, as shown in FIGS. 3-8, a driving current generated by the driving transistor T3 is transmitted to the second conductive plate CC2 of the storage capacitor CST through the third via hole GK3; the driving current transmitted to the second conductive plate CC2 of the storage capacitor CST is transmitted to the anode adaptor part YZB through the tenth via hole GK10; and the driving current transmitted to the anode adaptor part YZB is transmitted to the anode connecting part YLB through the ninth via hole GK9.

It should be noted that the via holes may be isotropic or anisotropic. For example, an orthographic projection of the via hole on the substrate may be circular, rectangular, hexagonal, etc., which is not limited herein.

Based on the same inventive concept, an embodiment of the disclosure further provides a display apparatus, which includes the display panel provided in the embodiments of the disclosure. The display apparatus may be any product or component with a display function, such as a smart watch, a mobile phone, a tablet computer, a television, a display, a notebook computer, a digital photo frame, or a navigator. Other essential components of the display apparatus should be understood by those of ordinary skill in the art, which are not repeated herein and should not limit the present disclosure. Reference may be made to the embodiments of the electroluminescent display panel for the implementation of the display apparatus, which are not repeated herein.

Although preferred embodiments of the disclosure have been described, those skilled in the art can still make additional changes and modifications to the embodiments once they learn the basic inventive concept. Therefore, the appended claims are intended to be interpreted as including the preferred embodiments and all changes and modifications falling within the scope of the disclosure.

Apparently, those skilled in the art can make various modifications and variations to the embodiments of the disclosure without departing from the spirit and scope of the embodiments of the disclosure. In this way, if these modifications and variations of the embodiments of the disclosure fall within the scope of the claims of the disclosure and their equivalent technologies, the present disclosure is also intended to include these modifications and variations.

1-47. (canceled)

48. A display panel, comprising:
a substrate comprising a plurality of sub-pixels;
an active semiconductor layer on the substrate;
a gate insulating layer on a side of the active semiconductor layer facing away from the substrate;
a first conductive layer on a side of the gate insulating layer facing away from the substrate;
an interlayer dielectric layer on a side of the first conductive layer facing away from the substrate;
a second conductive layer on a side of the interlayer dielectric layer facing away from the substrate;
a first interlayer insulating layer on a side of the second conductive layer facing away from the substrate;
a third conductive layer on a side of the first interlayer insulating layer facing away from the substrate, wherein the third conductive layer comprises a plurality of first signal lines that are spaced from each other;
a second interlayer insulating layer on a side of the third conductive layer facing away from the substrate; and
a fourth conductive layer on a side of the second interlayer insulating layer facing away from the substrate, wherein the fourth conductive layer comprises a plurality of second signal lines that are spaced from each other;
wherein an orthographic projection of the first signal line on the substrate intersect with an orthographic projection of the second signal line on the substrate.

49. The display panel according to claim 48, wherein the first signal line is a data line, and the second signal line is a power line.

50. The display panel according to claim 49, wherein the first conductive layer comprises a plurality of scanning lines that are spaced from each other, and the scanning line has a same extension direction as the power line;
the fourth conductive layer further comprises a plurality of reset lines that are spaced from each other, and the reset line has a same extension direction as the power line; and
for a power line, a scanning line and a reset line corresponding to one row of pixel circuits, an orthographic projection of the scanning line on the substrate is located between an orthographic projection of the power line on the substrate and an orthographic projection of the reset line on the substrate.

51. The display panel according to claim 48, wherein the pixel circuit comprises a driving transistor, a data writing transistor, a reset transistor, and a storage capacitor;
a first electrode of the driving transistor is electrically connected with the power line, and a second electrode of the driving transistor is electrically connected with a light emitting element;
a first conductive plate of the storage capacitor is electrically connected with a gate of the driving transistor, and a second conductive plate of the storage capacitor is electrically connected with the second electrode of the driving transistor;
a gate of the data writing transistor is electrically connected with the scanning line, a first electrode of the data writing transistor is electrically connected with the data line, and a second electrode of the data writing transistor is electrically connected with the gate of the driving transistor; and
a gate of the reset transistor is electrically connected with the scanning line, a first electrode of the reset transistor is electrically connected with the reset line, and a second electrode of the reset transistor is electrically connected with the second electrode of the driving transistor.

52. The display panel according to claim 51, wherein the active semiconductor layer comprises an active zone of the driving transistor, the first conductive layer comprises the first conductive plate of the storage capacitor, and the first conductive plate of the storage capacitor is reused as the gate of the driving transistor;
in the sub-pixel, an orthographic projection of the first conductive plate of the storage capacitor on the substrate has an overlapping region with an orthographic projection of a channel zone of the active zone of the driving transistor on the substrate; and
in the sub-pixel, the channel zone of the active zone of the driving transistor comprises a first driving channel zone and a second driving channel zone connected with each other, wherein the first driving channel zone extends in a first direction, the second driving channel zone extends in a third direction, and an included angle β between the first direction and the third direction satisfies 0°<β≤90°.

53. The display panel according to claim 52, wherein the active semiconductor layer further comprises an active zone of the reset transistor, wherein the active zone of the reset transistor extends in the first direction, and the active zone of the reset transistor is located at a side of the second driving channel zone of the driving transistor facing away from the first driving channel zone; and
in a same sub-pixel, a conducting drain zone of the active zone of the reset transistor is connected with the second driving channel zone of the driving transistor.

54. The display panel according to claim 53, wherein the active semiconductor layer further comprises an active zone of the data writing transistor, and the active zone of the data writing transistor is spaced from the active zone of the reset transistor and the active zone of the driving transistor respectively, wherein the active zone of the data writing transistor extends in the first direction; and
in the same sub-pixel, an orthographic projection of the active zone of the data writing transistor in a second direction is located at a side of an orthographic projection of the second driving channel zone of the driving transistor in the second direction facing away from an orthographic projection of the active zone of the reset transistor in the second direction.

55. The display panel according to claim 54, wherein in the same sub-pixel, a channel zone of the active zone of the data writing transistor and a channel zone of the active zone of the reset transistor are arranged in the second direction.

56. The display panel according to claim 50, wherein the second conductive layer comprises a data adaptor part in each sub-pixel;
the first conductive plate of the storage capacitor comprises a first conductive plate body part and a first conductive plate protrusion part electrically connected with each other; and
in the same sub-pixel, a first end of the data adaptor part is electrically connected with a conducting drain zone of the active zone of the data writing transistor through a first via hole, and a second end of the data adaptor part is electrically connected with the first conductive plate protrusion part through a second via hole, wherein the first via hole runs through the gate insulating layer and the interlayer dielectric layer, and the second via hole runs through the interlayer dielectric layer.

57. The display panel according to claim 56, wherein the second conductive layer further comprises the second conductive plate of the storage capacitor, wherein the second conductive plate of the storage capacitor comprises a second conductive plate body part and a second conductive plate protrusion part electrically connected with each other; and
in the same sub-pixel, the second conductive plate protrusion part is electrically connected with the conducting drain zone of the active zone of the reset transistor through a third via hole, wherein the third via hole runs through the interlayer dielectric layer and the gate insulating layer.

58. The display panel according to claim 57, wherein in the same sub-pixel, an orthographic projection of the first conductive plate body part on the substrate has an overlapping region with an orthographic projection of the second conductive plate body part on the substrate;
wherein the second conductive plate of the storage capacitor further comprises: a second conductive plate compensation part electrically connected with the second conductive plate body part and the second conductive plate protrusion part respectively, wherein the second conductive plate compensation part is located at a corner formed by the second conductive plate body part and the second conductive plate protrusion part; and
in the same sub-pixel, an orthographic projection of the second conductive plate compensation part on the substrate has an overlapping region with the orthographic projection of the first conductive plate body part on the substrate.

59. The display panel according to claim 51, wherein one column of the sub-pixels correspond to one data line; and
in the same sub-pixel, the data line is electrically connected with a conducting source zone of the active zone of the data writing transistor through a fourth via hole, wherein the fourth via hole runs through the first interlayer insulating layer, the interlayer dielectric layer and the gate insulating layer, and an orthographic projection of the fourth via hole on the substrate is located at a side of the orthographic projection of the scanning line on the substrate facing away from the orthographic projection of the first conductive plate of the storage capacitor on the substrate.

60. The display panel according to claim 59, further comprising at least one of following:
one power line corresponds to at least one row of the sub-pixels; and
the third conductive layer further comprises a plurality of power adaptor parts that are spaced from each other, wherein in the same sub-pixel,
the power line is electrically connected with the power adaptor part through a fifth via hole; and
the power adaptor part is electrically connected with a conducting source zone of the active zone of the driving transistor through a sixth via hole;
wherein the fifth via hole runs through the second interlayer insulating layer, and the sixth via hole runs through the first interlayer insulating layer, the interlayer dielectric layer, and the gate insulating layer;
or
one reset line corresponds to at least one row of the sub-pixels; and
the third conductive layer further comprises a plurality of reset adaptor parts that are spaced from each other; and in the same sub-pixel,
the reset line is electrically connected with the reset adaptor part through a seventh via hole; and
the reset adaptor part is electrically connected with a conducting source zone of the active zone of the reset transistor through an eighth via hole;
wherein the seventh via hole runs through the second interlayer insulating layer, and the eighth via hole runs through the first interlayer insulating layer, the interlayer dielectric layer, and the gate insulating layer.

61. The display panel according to claim 51, wherein the fourth conductive layer further comprises a plurality of anode connecting parts that are spaced from each other; and the third conductive layer further comprises a plurality of anode adaptor parts that are spaced from each other, wherein one sub-pixels comprises one anode connecting part and one anode adaptor part; and
in the same sub-pixel,
the anode connecting part is electrically connected with a first end of the anode adaptor part through a ninth via hole; and
a second end of the anode adaptor part is electrically connected with the second conductive plate of the storage capacitor through a tenth via hole;
wherein the ninth via hole runs through the second interlayer insulating layer, and the tenth via hole runs through the first interlayer insulating layer.

62. The display panel according to claim 61, wherein in a same column of the sub-pixels, anode connecting parts are arranged in the first direction and are not arranged on a same straight line; and
in a same row of the sub-pixels, anode connecting parts are arranged in the second direction and are not arranged on the same straight line;
or
wherein in a same column of the sub-pixels, anode adaptor parts are arranged on a same straight line in the first direction; and
in a same row of the sub-pixels, anode adaptor parts are arranged on a same straight line in the second direction.

63. The display panel according to claim 48, wherein in two adjacent sub-pixels, orthographic projections of pixel circuits on the substrate are arranged in a mirror symmetry manner.

64. The display panel according to claim 63, wherein two adjacent rows of sub-pixels form a row group, and different row groups comprise different sub-pixels; and
two scanning lines corresponding to the row group have a row symmetry axis in a row direction, and orthographic projections of pixel circuits in the sub-pixels of the same row group on the substrate are arranged in a mirror symmetry manner with respect to the row symmetry axis;
wherein two adjacent columns of sub-pixels in the same row group form a column group, and different column groups comprise different sub-pixels; and
two data lines corresponding to the column group have a column symmetry axis in a column direction, and orthographic projections of pixel circuits in the same column group of sub-pixels on the substrate are arranged in a mirror symmetry manner with respect to the column symmetry axis.

65. The display panel according to claim 48, wherein the same row group of sub-pixels share one power line; and
orthographic projections of pixel circuits located in the same column and at two sides of the power line on the substrate are arranged symmetrically with respect to the orthographic projection of the power line on the substrate.

66. The display panel according to claim 48, wherein two adjacent rows of sub-pixels located in different row groups share one reset line; and
orthographic projections of pixel circuits located in the same column and at two sides of the reset line on the substrate are arranged symmetrically with respect to the orthographic projection of the reset line on the substrate;
wherein for two rows of sub-pixels sharing the same reset line, two adjacent columns of sub-pixels in the two rows of sub-pixels share one reset adaptor part.

67. A display apparatus, comprising a display panel, wherein the display panel comprises:
a substrate comprising a plurality of sub-pixels;
an active semiconductor layer on the substrate;
a gate insulating layer on a side of the active semiconductor layer facing away from the substrate;
a first conductive layer on a side of the gate insulating layer facing away from the substrate;
an interlayer dielectric layer on a side of the first conductive layer facing away from the substrate;
a second conductive layer on a side of the interlayer dielectric layer facing away from the substrate;
a first interlayer insulating layer on a side of the second conductive layer facing away from the substrate;
a third conductive layer on a side of the first interlayer insulating layer facing away from the substrate, wherein the third conductive layer comprises a plurality of first signal lines that are spaced from each other;
a second interlayer insulating layer on a side of the third conductive layer facing away from the substrate; and
a fourth conductive layer on a side of the second interlayer insulating layer facing away from the substrate, wherein the fourth conductive layer comprises a plurality of second signal lines that are spaced from each other;
wherein an orthographic projection of the first signal line on the substrate intersect with an orthographic projection of the second signal line on the substrate.
